(19) United States
(12) Patent Application Publication
(10) Pub. No.: US 2025/0218748 A1
(43) Pub. Date: Jul. 3, 2025

(54) AIR-CORE COIL IN ANALOG CIRCUIT FILTERS FOR PLASMA PROCESSING

(71) Applicant: APPLIED MATERIALS, INC., Santa Clara, CA (US)

(72) Inventors: Yue Guo, Redwood City, CA (US); Kartik Ramaswamy, San Jose, CA (US)

(21) Appl. No.: 18/397,234

(22) Filed: Dec. 27, 2023

(51) Int. Cl. H01J 37/32

(52) U.S. Cl. CPC H01J 37/32715; H01J 37/32183; H01J 37/32568; H01J 2237/3341

(57) ABSTRACT

A system includes a processing chamber configured to perform a plasma process with respect to one or more substrates. The system further includes an electrostatic chuck disposed within the processing chamber. The electrostatic chuck includes one or more electrodes. The system further includes an analog filter electrically coupled to at least one electrode of the one or more electrodes. The analog filter includes an air-core coil including a first coil and a second coil disposed within the first coil. The first coil and the second coil together form an inductor.

### TECHNICAL FIELD

Embodiments of the present disclosure generally relate to an analog circuit filter used in plasma processing of substrates. More specifically, embodiments provided herein generally include an air-core coil that forms an inductor for inclusion in analog circuit filters used in plasma processing.

### BACKGROUND

Plasma is often used to process substrates. Plasma can be created in a processing chamber by exciting a gas or a mixture of gases using a radio frequency (RF) signal and/or a pulsed voltage (PV) waveform signal. Such signals can be propagated through electrical components of the processing chamber and may cause damage to such electrical components.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

Some embodiments described herein cover a system including a processing chamber configured to perform a plasma process with respect to one or more substrates. The system further includes an electrostatic chuck disposed within the processing chamber. The electrostatic chuck includes one or more electrodes. The system further includes an analog filter electrically coupled to at least one electrode of the one or more electrodes. The analog filter includes an air-core coil including a first coil and a second coil disposed within the first coil. The first coil and the second coil together form an inductor.

Additional or related embodiments described herein cover a plasma processing system including a pulsed voltage (PV) waveform generator configured to provide a PV waveform signal to a plasma processing chamber. The plasma processing system further includes one or more electrodes disposed within a substrate support within the plasma processing chamber. The plasma processing system further includes an analog filter electrically coupled to at least one electrode of the one or more electrodes. The analog filter includes a choke electrically in series with an air-core coil. The air-core coil forms an inductor.

Further embodiments described herein cover a system including one or more electrodes of a plasma processing chamber. The system further includes an air-core coil electrically coupled to at least one of the one or more electrodes. The air-core coil includes a first coil and a second coil electrically in series with the first coil. The second coil is disposed within the first coil. The air-core coil forms an inductor configured to at least partially block one or more of a radio frequency (RF) signal or a pulsed voltage (PV) waveform signal from passing through the air-core coil.

Numerous other features are provided in accordance with these and other aspects of the disclosure. Other features and aspects of the present disclosure will become more fully apparent from the following detailed description, the claims, and the accompanying drawings.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to have the same embodiment, and such references mean at least one.

FIGS. 1A-1B are simplified schematic representations of a plasma processing system, according to one or more embodiments.

FIG. 1C is a schematic cross-sectional view of a plasma processing system that can be configured to perform one or more of the plasma processing methods described herein, according to one or more embodiments.

FIG. 2 illustrates voltage pulses provided within a voltage waveform that is established at a substrate due to the delivery of voltage pulses to a biasing electrode during plasma processing, according to one or more embodiments

FIG. 3 is schematic representations of a junction box of the plasma processing system, according to one or more embodiments.

FIG. 4 is a schematic representation of a RF power delivery system, according to one or more embodiments

FIGS. 5A-D are schematic representations of analog filters for a plasma processing system, according to one or more embodiments.

FIG. 6 is a simplified perspective view of an air-core coil, according to one or more embodiments.

### DETAILED DESCRIPTION OF EMBODIMENTS

Embodiments of the present disclosure are directed to an air-core coil for use in analog circuit filters for plasma processing (e.g., processing of substrates, etc.).

In some embodiments, features are formed on substrates using plasma-assisted etching processes, such as a reactive ion etch (RIE) plasma process. In a typical RIE plasma process, a plasma is formed in a processing chamber and ions from the plasma are accelerated towards a surface of a substrate to form openings in a material layer disposed beneath a mask layer formed on the surface of the substrate.

A typical RIE plasma processing chamber includes a radio frequency (RF) bias generator, which supplies an RF voltage to a power electrode. In a capacitively coupled gas discharge, the plasma is created by using an RF generator that is electrically coupled to the power electrode disposed within an electrostatic chuck (ESC) assembly or within another portion and/or component of the processing chamber. The RF generator may generate an RF signal that is conveyed to the power electrode. Typically, an RF matching network (“RF match”) tunes an RF waveform provided from an RF generator to deliver RF power to an apparent load of 50Q to reduce the reflected power and improve the power delivery efficiency.

Some plasma processes utilize DC voltage pulsing schemes to control the plasma sheath disposed over the substrate that is being processed. During operation, high DC voltage pulses are provided by a high voltage DC supply that are used to provide a negative bias to a biasing electrode while a pulsed voltage (PV) waveform signal is provided by a PV waveform generated to the biasing electrode simultaneously. The voltage provided to the biasing electrode is equal to the sum of the high DC voltage pulses and the PV waveform.

Often, the RF signal and/or PV waveform signal can be conveyed from the ESC back through other electrical components, such as AC and/or DC power circuits (e.g., AC and/or DC power lines, etc.). For example, an electrode such as a heater electrode in the ESC may be powered using an AC power line. The RF signal and/or PV waveform signal may be coupled (e.g., reflected) back through the electrode and the AC power line, and may damage components that make up the AC power source, such as circuits, breakers, the power line itself, etc. The coupled RF signal and/or PV waveform signal in the power line may cause arcing and/or overheating issues that may severely damage circuit components. Coupling (e.g., reflection) of RF and/or PV waveform signals becomes especially problematic at low frequencies, such as at frequencies below 5 megahertz (MHz) because conventional filters or chokes do not adequately protect against signals at these frequencies. Design and construction of analog circuit filters to adequately filter such low frequency signals is often problematic.

Conventionally, electronic chokes (e.g., common mode chokes, ferrite chokes, etc.) are used to filter and/or attenuate RF and/or PV waveform signals coupled through power lines. Electronic chokes often include an inductor used to block high frequency signals (e.g., such as high frequency RF and/or PV waveform signals) in a circuit. A choke typically includes a coil of insulated wire often wound around a core. Some chokes, such as common mode chokes (e.g., ferrite chokes, etc.), include a doughnut-shaped ferrite bead on a wire. Although conventional chokes can block high-frequency signals, conventional chokes perform poorly for blocking and/or attenuating low-frequency, high-energy signals such as RF signals having a frequency less than 5 MHz and/or PV waveform signals having a frequency less than 2 MHz. Often, conventional chokes become voltage saturated by the low frequency signals. Once a choke becomes voltage saturated, the effectiveness of the choke diminishes significantly. Therefore, a voltage saturated choke may allow low frequency RF and/or PV waveform signals to pass, which may cause damage to other circuitry components as described herein above. One solution is to add a large inductor electrically in series with the choke. However, the inductor is often too large to fit within size constraints of the system.

Aspects and implementations of the instant disclosure address the above-described and other shortcomings of conventional systems by providing a system having an air-core coil that forms an inductor. The air-core coil may be included on power supply lines (e.g., AC power and/or DC power supply lines) to block RF and/or PV waveform signals from propagating through the power lines. The air-core coil may increase the impedance of the power supply lines, causing the RF and/or PV waveform signals to couple through the plasma and then to ground. The air-core coil may be a multi-layer coil having a first coil and a second coil disposed within the first coil. The coils may be wound to increase the inductance of the coil, providing an efficient and cost-effective way to mitigate saturation of conventional electronic chokes. The air-core coil described herein can be included in analog circuit filters such as a low-pass filter, a band-stop filter, a resonant circuit, and/or a combination thereof.

In some embodiments, a system includes a processing chamber that is configured to perform a plasma process with respect to one or more substrates. The processing chamber may be configured to perform an etch process such as a RIE process. The processing chamber may include several components, including gas distribution component(s) and electrode(s) for inducing plasma within the chamber. An RF generator and/or a PV waveform generator may provide a signal to the electrode(s) for generating the plasma. In some embodiments, the processing chamber includes a substrate support, such as an electrostatic chuck (ESC), to support a substrate during the plasma process. The substrate support may include one or more heater electrodes (e.g., heaters) to provide heat to the substrate under process and/or to provide heat to the processing environment.

In some embodiments, the one or more electrodes (e.g., heater electrodes, heaters, etc.) of the substrate support are powered by electrical energy, such as AC electrical current or DC electrical current. A power source provides the electrical current for powering the one or more electrodes. The power source and/or associated circuitry may include components that are susceptible to damage from RF and/or PV waveform signals. In some embodiments, the system includes an analog filter electrically coupled to at least one of the one or more electrodes. The analog filter may include a low-pass filter and/or a band-stop filter as described herein. The filter may filter out high frequency signals (such as RF and/or PV waveform signals) that may otherwise cause damage to the circuitry components. In some embodiments, the filter is electrically coupled between the electrode and the power source to protect the power source from the RF and/or PV waveform signals.

In some embodiments, the analog filter includes an air-core coil. The air-core coil may include a first coil and a second coil disposed within the first coil. The first coil and the second coil may together form an inductor. In some embodiments, the inductor is configured to at least partially block an RF signal and/or a PV waveform signal from passing through the air-core coil. In some embodiments, the second coil is folded with respect to the first coil so that the second coil is disposed within the first coil. This folded arrangement may the size of the air-core coil while increasing the inductance of the air-core coil. For example, the magnetic field of the first coil and the magnetic field of the second coil may complement one another to increase the aggregate inductance of the air-core coil.

Embodiments of the present disclosure provide advantages over conventional systems described above. Particularly, inclusion of an air-core coil between a power source (e.g., an AC power source) and a component of the processing chamber (e.g., such as a heater electrode or other electrode of a substrate support, etc.) may more effectively protect the power source from damage caused by RF and/or PV waveform signals when compared to conventional solutions. When used in series with a conventional choke (e.g., such as a common mode choke), the air-core coil may protect against voltage saturation of the choke. This can allow the choke to effectively block RF and/or PV waveform signals regardless of the strength and/or duration of the signals. Moreover, the air-core coil, when used in an analog filter as described herein, can provide enhanced filter performance, especially for applications with low frequency (e.g., less than 5 MHz and/or less than 2 MHz RF and/or PV waveform signals. The air-core coil may be more cost effective than conventional solutions while also having a smaller size due to the ‘folded’ arrangement of coils that make up the air-core coil. By including the air-core coil in analog circuit filters used for plasma processing, damage to related circuitry components can be reduced, reducing overall cost associated with plasma processing and reducing risk of accidents such as fire.

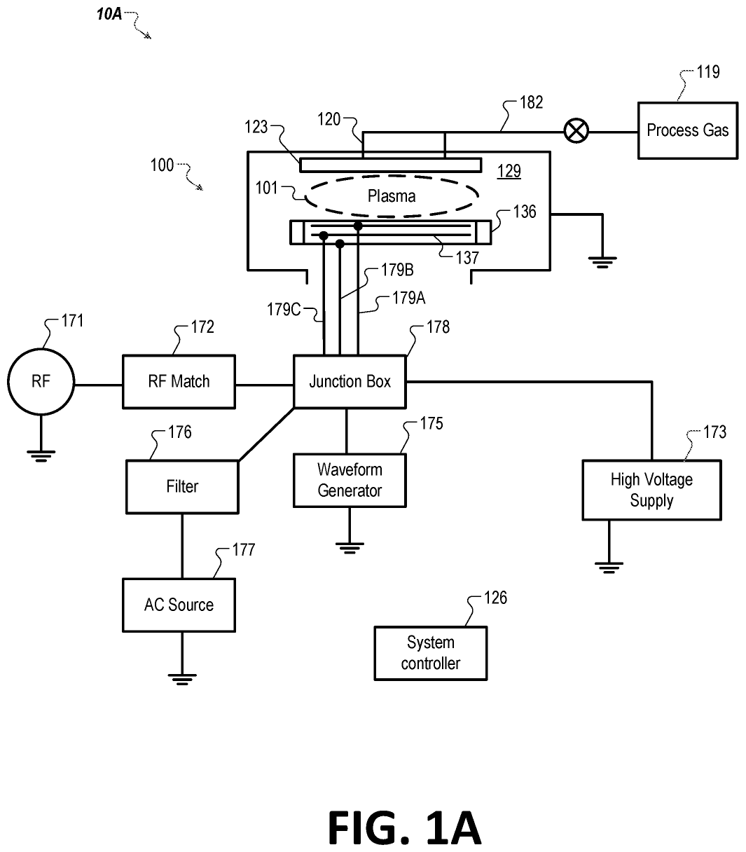

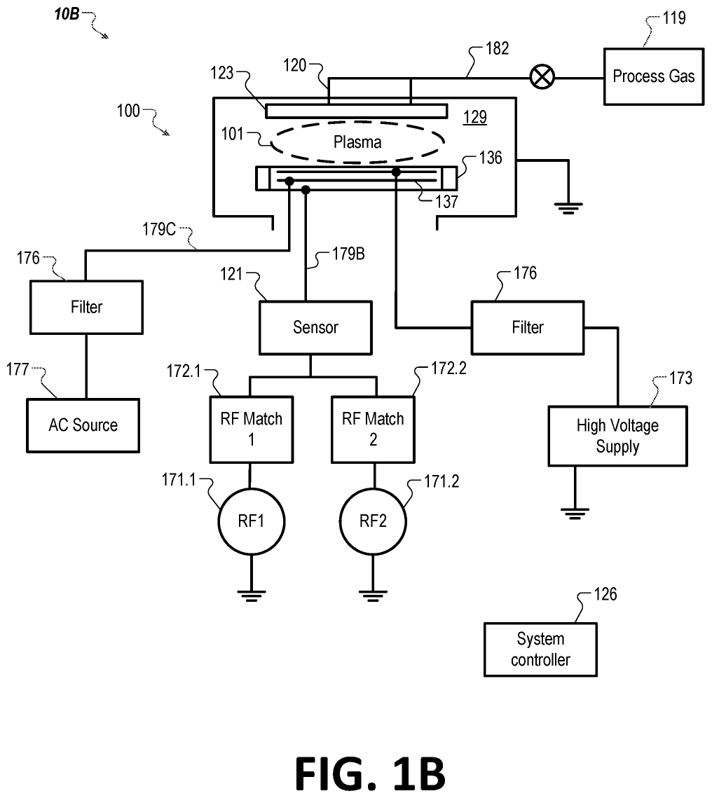

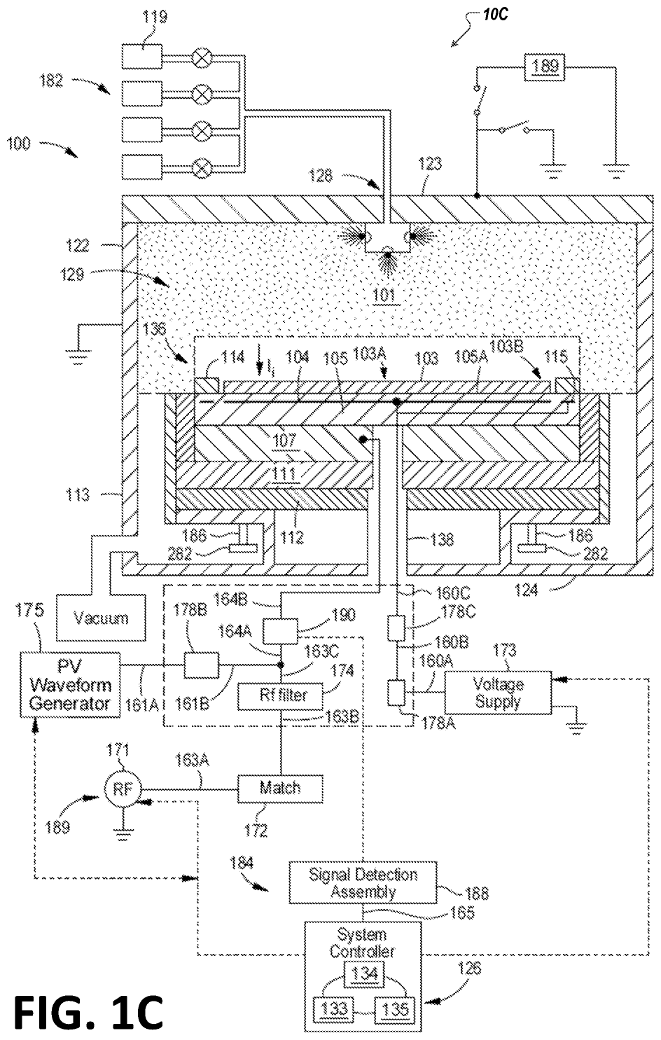

FIGS. 1A-1B are simplified schematic representations of a plasma processing system, according to one or more embodiments. Referring to FIG. 1A, a plasma processing system 10A is configured for plasma-assisted etching processes, such as a reactive ion etch (RIE) plasma processing. The plasma processing system 10A can also be used in other plasma-assisted processes, such as plasma-enhanced deposition processes (for example, plasma-enhanced chemical vapor deposition (PECVD) processes, plasma-enhanced physical vapor deposition (PEPVD) processes, plasma-enhanced atomic layer deposition (PEALD) processes, plasma treatment processing, plasma-based ion implant processing, or plasma doping (PLAD) processing. In one configuration, as shown in FIG. 1A, the plasma processing system 10A is configured to form a capacitive coupled plasma (CCP). However, in some embodiments, a plasma may alternately be generated by an inductively coupled source disposed over a processing region of the plasma processing system 10A.

The plasma processing system 10A includes a processing chamber 100, a substrate support assembly 136, a gas delivery system 182, a high voltage supply 173, a radio frequency (RF) generator 171, an RF match 172 (e.g., RF impedance matching network), an AC source 177, and an analog circuit filter 176. A chamber lid 123 includes one or more sidewalls and a chamber base that are configured to withstand the pressures and energy applied to them while a plasma 101 is generated within a vacuum environment maintained in a processing volume 129 of the processing chamber 100 during processing.

The gas delivery system 182, which is coupled to the processing volume 129 of the processing chamber 100, is configured to deliver at least one processing gas from at least one gas processing source 119 to the processing volume 129 of the processing chamber 100. The gas delivery system 182 includes the processing gas source 119 and one or more gas inlets 128 (see FIG. 1C) positioned through the chamber lid 123. The gas inlets 128 are configured to deliver one or more processing gasses to the processing volume 129 of the processing chamber 100.

The processing chamber 100 includes an upper electrode (e.g., the chamber lid 123) and a lower electrode (e.g., the substrate support assembly 136) positioned in the processing volume 129 of the processing chamber 100. The upper and lower electrodes face one another. In some embodiments, the RF generator 171 is electrically coupled to the lower electrode. The RF generator 171 is configured to deliver an RF signal to ignite and maintain the plasma 101 between the upper and lower electrodes. In some alternative configurations, the RF generator 171 can also be electrically coupled to the upper electrode. For example, the RF generator 171 may deliver an RF source power to an RF baseplate within a cathode assembly (e.g., in the substrate support assembly 136) for plasma production, whereas the upper electrode is grounded. In some embodiments, a separate RF generator (not illustrated) is configured to deliver an RF signal to the upper electrode or to an RF coil disposed in the upper portion of the processing chamber 100. The separate RF generator may include a separate corresponding RF match. RF signals may be supplied to the upper and lower electrodes for plasma production.

A center frequency of the RF source power can be from 13.56 MHz to very high frequency band such as 40 MHz, 60 MHz, 120 MHz or 162 MHz. In some embodiments, a center frequency of the RF source power can be below 50 MHz. In some embodiments, a center frequency of the RF source power can be below 5 MHz. In some embodiments, the RF source power can also be delivered through the upper electrode. The RF source power can be operated in a continuous mode or a pulsed mode. The RF power may have a pulsing frequency from 100 Hz to 10 kHz, and duty cycle ranging from 5% to 95%. The RF generator 171 has frequency tuning capability and can adjust the RF power frequency within e.g., ±5% or ±10%. In some embodiments, the RF generator 171 switches the RF power frequency at a predefined speed (e.g., two nanoseconds, fifty nanoseconds, etc.).

The substrate support assembly 136 may be coupled to a high voltage supply 173 that supplies a chucking voltage thereto. The RF generator 171 and the high voltage supply 173 may be coupled to a junction box 178 that is disposed between the high voltage supply 173 and the substrate support assembly 136. The junction box 178 may be coupled to the substrate support assembly 136 by a DC power line 179A.

In some embodiments, the substrate support assembly 136 is coupled to the RF generator 171 which is configured to deliver an RF signal to the processing volume 129 of the processing chamber 100. The RF generator 171 is electrically coupled to the junction box 178 via an RF match 172. For example, the RF match 172 is an electrical circuit used between the RF generator 171 and a plasma reactor (e.g., the processing volume 129 of the processing chamber 100) to optimize power delivery efficiency. One or more RF filters (e.g., within the RF match 172, or the junction box 178) are designed to only allow powers in a selected frequency range, and to isolate RF power supplies from each other. In some cases, a bandwidth of an RF filter has to be larger than a frequency tuning range of the RF generator 171. The RF match 172 may or may not be included in the junction box 178.

During plasma processing, the RF generator 171 delivers an RF signal to the substrate support assembly 136 via the junction box 178 and RF signal line 179B. From the substrate support assembly 136, the RF signal is applied to a load (e.g., gas) in the processing volume 129 of the processing chamber 100. If an impedance of the load is not properly matched to an impedance of a source (e.g., the RF generator 171), a portion of a waveform can reflect back in an opposite direction. Accordingly, to prevent a substantial portion of the waveform from reflecting back, a match impedance (e.g., a matching point) is maintained by adjusting one or more components of the RF match 172 as the source and load impedances change.

The RF match 172 may be electrically coupled to the RF generator 171 and the substrate support assembly 136. The RF match 172 may be configured to receive a synchronization signal from either or both of the RF generator 171.

In some embodiments, the PV waveform generator 175 is used to supply a PV waveform signal and/or a tailored voltage waveform, which is a sum of harmonic frequencies associated with the waveform. The PV waveform generator 175 may output a synchronization TTL signal. In some embodiments, the PV waveform generator 175 and the RF generator 171 are coupled to a same electrode of the substrate support assembly 136 (e.g., substrate support base 107 shown in FIG. 1C) through the junction box 178. The high voltage supply 173 is applied to an electrode of the substrate support (e.g., biasing electrode 104 shown in FIG. 1C) to chuck a wafer during a process for thermal control. In some embodiments, there can be a third electrode at an edge of the substrate support assembly 136 for edge uniformity control.

The RF generator 171 and the PV waveform generator 175 may each be directly coupled to a system controller 123. The system controller 126 may synchronize the respective generated RF signal and PV waveform.

In some embodiments, the AC source 177 is an electrical source used to supply alternating current (AC) to an electrode (e.g., such as a heater electrode, a heater, etc.) disposed in the substrate support assembly 136. The AC source 177 may provide electrical energy (e.g., AC current, etc.) to the electrode e.g., for heating of a substrate for processing. In some embodiments, the AC source 177 supplies AC to a heating element 137 via the junction box 178 and AC heater line 179C. In some embodiments, the AC source 177 is coupled to the system controller 126. The AC supplied by the AC source may pass through a filter 176. In some embodiments, the filter 176 is to block the RF signal and/or the PV waveform signal from reaching the AC source 177. Without the filter 176, the RF signal and/or the PV waveform signal may reflect back along the AC circuit lines from the substrate support 136 to the AC source 177 and may cause damage (e.g., such as circuit shorts, burning breakers, etc.) to the AC source 177. In some embodiments, the substrate support assembly 136 includes multiple heaters (e.g., multiple heater electrodes) each associated with one or more heating zones. A corresponding analog filter may be electrically coupled to each of the heaters. In some embodiments, each heater and/or heater zone may be supplied electrical energy by a distinct AC source 177. Each distinct AC source 177 may be coupled to the corresponding heater and/or heater zone via a distinct filter 176. For example, where there are eight heater zones in substrate support assembly 136, each of the eight heater zones is supplied with AC from one of eight different AC sources 177. Each of the eight different AC sources are coupled to the eight heater zones by one of eight different filters 176.

The filter 176 may include an analog circuit filter, such as a low-pass filter and/or a band-stop filter. In some embodiments, the filter 176 includes an air-core coil as described herein. The air-core coil may form an inductor. In some embodiments, the air-core coil is electrically in series with a choke, such as a common mode choke. The filter 176 may protect the AC source 177 from damage from the RF signal and/or from the PV waveform signal.

Referring to FIG. 1B, a plasma processing system 10B is shown. In some embodiments, system 10B includes a first RF generator 171.1 and a second RF generator 171.2. Each of the first and second RF generators 171.1 and 171.2 may function substantially the same as RF generator 171 described herein above with respect to FIG. 1A. Including two RF generators may allow for more complex RF signals for igniting/generating plasma 101 than when using a single RF generator, such as in system 10A. Each RF generator may be electrically coupled to a corresponding RF match. For example, first RF generator 171.1 may be coupled to a first RF Match 172.1 and second RF generator 171.2 may be coupled to a second RF match 172.2. Each of the first and second RF matches 172.1 and 172.2 may function substantially the same as RF match 172 described herein above with respect to FIG. 1A.

In some embodiments, each of the RF generators 171.1 and 171.2 are coupled to an electrode in the chamber 100 (e.g., such as an electrode in substrate support 136) via a sensor 121. In some embodiments, sensor 121 senses the RF signal provided by the RF generator(s). Sensor data from the sensor 121 may be provided to the system controller 126 for controlling the RF generators 171.1 and/or 171.2.

In some embodiments, the high voltage supply 173 is coupled to the substrate support assembly 136 via a filter 176. In some embodiments, the filter 176 blocks an RF signal from coupling (e.g., reflecting) from the chamber 100 to the high voltage supply 173. As described herein above, the filter 176 may include an air-core coil and/or an analog filter such as a low-pass filter and/or a band-stop filter. Without filter 176, an RF signal may propagate along the high voltage supply power lines from the substrate support assembly 136 and may damage the high voltage supply 173.

FIG. 1C is a schematic detailed cross-sectional view of the plasma processing system 10. In one configuration, as shown in FIG. 1C, the plasma processing system 10C is configured to form a capacitively coupled plasma (CCP). However, in some embodiments, a plasma 101 may alternately be generated by use of an inductively coupled source disposed over the processing volume 129 of the plasma processing system 10C. In this configuration, a coil may be placed on top of a ceramic lid (vacuum boundary) of the processing chamber 100.

The plasma processing system 10C includes the processing chamber 100, the substrate support assembly 136, the gas delivery system 182, an RF power system 189, and a system controller 126. As shown in FIG. 1C, the processing chamber 100 includes a chamber body 113 that comprises a chamber lid 123, one or more sidewalls 122, and a chamber base 124. The chamber lid 123, one or more sidewalls 122, and the chamber base 124 collectively define the processing volume 129. The one or more sidewalls 122 and chamber base 124 generally include materials (such as aluminum, aluminum alloys, or stainless steel alloys) that are sized and shaped to form the structural support for the elements of the processing chamber 100. The one or more sidewalls 122 and chamber base 124 are configured to withstand the vacuum pressures and energy used to sustain a plasma 101 within the processing volume 129 of the processing chamber 100. A substrate 103 is loaded into, and removed from, the processing volume 129 through an opening (not shown) in one of the sidewalls 122. The opening is sealed with a slit valve (also not shown) during plasma processing of the substrate 103.

The gas delivery system 182, which is coupled to the processing volume 129 of the processing chamber 100, includes a processing gas source 119 and a gas inlet 128 disposed through the chamber lid 123. The gas inlet 128 is configured to deliver one or more processing gases to the processing volume 129 from the plurality of processing gas sources 119.

The processing chamber 100 further includes an upper electrode (e.g., chamber lid 123) and the substrate support assembly 136 that are disposed in a processing volume 129. As shown in FIG. 1C, in one embodiment, a radio frequency (RF) generator 171 is electrically coupled to a lower electrode (e.g., substrate support base 107) disposed within the substrate support assembly 136. The RF generator 171 may be configured to deliver an RF signal to ignite and maintain the plasma 101 between the upper and lower electrodes. In some alternative configurations, the RF generator 171 can also be electrically coupled to an upper electrode, such as the chamber lid 123 directly, to form a capacitively coupled plasma (CCP), or through source coils to form inductively coupled plasmas (ICP).

The substrate support assembly 136 includes a substrate support 105, a substrate support base 107, an insulator plate 111, a ground plate 112, a plurality of lift pins 186, one or more substrate potential sensing assemblies 184, and a biasing electrode 104. The substrate potential sensing assemblies 184 include a signal detecting assembly 188 and one or more sensors 190. The substrate potential sensing assembly 184 is communicatively coupled to the system controller 126 via communication line 165. The signal detection assembly 188 generally includes components that are configured to receive a signal from a sensor 190 and form an output signal that can be used by the system controller 126. The system controller 126 can then use the received output signal to display a result or measurement performed by the sensor 190 and/or control some part of the processing chamber 100 or process performed therein. The system controller 126, can transform the output signal received from the sensor into meaningful plasma diagnostic signals including, but not limited to, the Vdc (plasma voltage on the wafer), ion flux, or other parameters that can be used for chamber matching, fault detection, or improved control of the RF generator 171, and/or the PV waveform generator 175. The one or more sensors 190 are coupled to the signal detection assembly 188 via the one or more communication lines 158. Each of the lift pins 186 are disposed through a through hole 185 formed in the substrate support assembly 136 and are used to facilitate the transfer of the substrate 103 to and from a substrate receiving surface 105A of the substrate support 105. The substrate support 105 is formed of a dielectric material. The dielectric material can include a bulk sintered ceramic material, a corrosion-resistant metal oxide (for example, aluminum oxide (Al₂O₃), titanium oxide (TiO), yttrium oxide (Y₂O₃), a metal nitride material (for example, aluminum nitride (AlN), titanium nitride (TiN)), mixtures thereof, or combinations thereof.

The substrate support base 107 is formed of a conductive material (for example aluminum, an aluminum alloy, or a stainless steel alloy). The substrate support base 107 is electrically isolated from the chamber base 124 by the insulator plate 111, and the ground plate 112 interposed between the insulator plate 111 and the chamber base 124. In some embodiments, the substrate support base 107 is configured to regulate the temperature of both the substrate support 105, and the substrate 103 disposed on the substrate support 105 during substrate processing. In some embodiments, the substrate support base 107 includes one or more cooling channels (not shown) disposed therein that are fluidly coupled to, and in fluid communication with, a coolant source (not shown), such as a refrigerant source or substrate source having a relatively high electrical resistance. In other embodiments, the substrate support 105 includes a heater (e.g., a heater electrode; not shown) to heat the substrate support 105 and substrate 103 disposed on the substrate support 105.

A biasing electrode 104 is embedded in the dielectric material of the substrate support 105. Typically, the biasing electrode 104 is formed of one or more electrically conductive parts. The electrically conductive parts typically include meshes, foils, plates, or combinations thereof. In some embodiments, the biasing electrode 104 can function as a chucking pole (i.e., electrostatic chucking electrode) that is used to secure (e.g., electrostatically chuck) the substrate 103 to the substrate receiving surface 105A of the substrate support 105. In general, a parallel plate like structure is formed by the biasing electrode 104 and a layer of the dielectric material that is disposed between the biasing electrode 104 and the substrate receiving surface 105A. The dielectric material can typically have an effective capacitance C_{E} of between about 5 nF and about 50 nF. Typically, the layer of dielectric material (e.g., aluminum nitride (AlN), aluminum oxide (Al₂O₃), etc.) has a thickness between about 0.03 mm and about 5 mm, such as between about 0.1 mm and about 3 mm, such as between about 0.1 mm and about 1 mm, or even between about 0.1 mm and 0.5 mm. The biasing electrode 104 is electrically coupled to a clamping network, which provides a chucking voltage thereto. The clamping network includes the high voltage supply 173 that is coupled to a bias compensation module (BCM) 178A of the junction box 178 that is disposed between the high voltage supply 173 and biasing electrode 104.

In some configurations, the substrate support assembly 136, further includes an edge control electrode 115. The edge control electrode 115 is formed of one or more electrically conductive parts. The electrically conductive parts typically include meshes, foils, plates, or combinations thereof. The edge control electrode 115 is positioned below the edge ring 114 and surrounds the biasing electrode 104 and/or is disposed a distance from a center of the biasing electrode 104. In general, for a processing chamber 100 that is configured to process circular substrates, the edge control electrode 115 is annular in shape, is made from a conductive material, and is configured to surround at least a portion of the biasing electrode 104. As seen in FIG. 1C, the edge control electrode 115 is positioned within a region of the substrate support 105, and is biased by use of an output provided from the high voltage supply 173. In one configuration, the edge control electrode 115 is biased by use of a PV waveform generator that is different from the PV waveform generator 175 used to biasing electrode 104. In another configuration, the edge control electrode 115 is biased by splitting part of the signal provided from the PV waveform generator 175 to the biasing electrode 104.

As shown in FIG. 1C, plasma processing system 10 includes the high voltage supply 173, the PV waveform generator 175, and a current source (not shown). In some embodiments, the current source is included in the high voltage supply 173. In another example, the current source is separate from the high voltage supply 173. The RF power system 189 includes a radio frequency (RF) generator 171 and RF match 172.

In some embodiments, a junction box 178 is electrically coupled to one or more components of both the RF power system 189 and the high voltage supply 173. The junction box 178 electrically isolates one or more of the components contained within the RF power system 189 and the high voltage supply 173. Additionally, the junction box 178 is configured to decouple the high voltage supply 173 and the PV waveform generator 175, as described above, to reduce the current provided to biasing electrode 104, reduce arcing, allow for a PV waveform with a higher voltage, and/or increase the voltage margin of the PV waveform generator 175 while maintaining the same etch rate. In some embodiments, the junction box 178 routes the outputs of the RF generator 171 and the PV waveform generator 175 to the substrate support base 107 and routes the output of the high voltage supply 173 to the biasing electrode 104. In some embodiments, junction box 178 includes and/or is coupled to one or more analog circuit filters having an air-core coil as described herein.

In some embodiments, the junction box 178 includes an RF filter 174, BCM 178A, a pulsed voltage (PV) filter 178B, a high voltage module (HVM) filter 178C, and sensor 190. In various embodiments, the junction box 178 is electrically coupled to the RF match 172, the high voltage supply 173, and the PV waveform generator 175. In other embodiments, the RF match 172 is included in the junction box 178 and the junction box is directly electrically coupled to the RF generator 171.

In some embodiments, the high voltage supply 173 is coupled to the biasing electrode 104 disposed within the substrate support assembly 136. The high voltage supply 173 is configured to supply a chucking voltage to the biasing electrode 104. The high voltage supply 173 is coupled to the biasing electrode via junction box 178. Power delivery line 160A electrically connects the output of the high voltage supply 173 to the BCM 178A of junction box 178. In some embodiments, the BCM 178A is a circuit configured to keep the chucking voltage stable and eliminate the effects of pulse-off. Power delivery line 160B electrically connects the output of BCM 178A to a high voltage module (HVM) filter 178C of junction box 178. In some embodiments, the HVM filter 178C is configured to isolate the high voltage supply 173 from other signals created within the processing chamber 100. For example, HVM filter 178C is configured to isolate the high voltage supply 173 from the signals generated from the RF generator 171 and the PV waveform generator 175. The HVM filter 178C may be any suitable filter that can protect the high voltage supply 173 such as a low-pass filter, a high-pass filter, a band-pass filter, or the like. In some embodiments, the HVM filter 178C is a low-pass filter.

Power delivery line 160C electrically connects the output of HVM filter 178C to biasing electrode 104. The HVM filter 178C removes interference from the RF and PV waveforms from getting back to the high voltage supply 173. In one configuration, the chucking voltage (i.e., static DC voltage) supplied by the high voltage supply 173 is between about −5000V and about 5000V, and is delivered using an electrical conductor (such as a coaxial power delivery lines 160A-160C).

In some embodiments, the PV waveform generator 175 is coupled to the substrate support base 107. In some embodiments, the PV waveform generator 175 is configured to deliver a pulse voltage (PV) waveform to the substrate support base 107 to bias the substrate support assembly 136. Power delivery line 161A electrically connects the output of the PV waveform generator 175 to PV filter 178B of junction box 178. In some embodiments, PV filter 178B is configured to isolate the PV waveform generator 175 from other signals created within the processing chamber 100. For example, PV filter 178B is configured to isolate the PV waveform generator 175 from the signals generated from the RF generator 171 and the high voltage supply 173. PV filter 178B may be any suitable filter that can protect the PV waveform generator 175 such as a low-pass filter, a high-pass filter, a band-pass filter, or the like. In some embodiments, the frequency of the PV waveform and the frequency of the PV filter 178B are the same. In another example the frequency of the PV waveform and the PV filter 178B are different. Power delivery line 161B electrically connects the output of PV filter 178B to output node n1.

In some embodiments, the RF generator 171 is configured to deliver an RF waveform (also known as an RF bias voltage signal) to bias the substrate support base 107 to ignite and maintain a plasma 101 in a processing volume 129 of the processing chamber 100. Power delivery line 163A electrically connects the output of the RF generator 171 to the RF match 172. The RF match 172 includes an RF matching network that tunes the RF waveform provided by the RF generator 171 to minimize the reflected power and improve the power delivery efficiency. If the impedance of the load is not properly matched to the impedance of the source (e.g., the RF generator), a portion of the RF waveform can reflect back in the opposite direction along the same transmission line. Stated differently, the RF match 172 is configured to receive an RF waveform from the RF generator 171, tune/match the impedance of the load to the impedance of the generator to reduce the reflected power and improve power delivery efficiency, and deliver the tuned RF waveform to the processing chamber 100. Power delivery line 163B electrically connects the output of the RF match 172 to RF filter 174 of junction box 178. In some embodiments, RF filter 174 is configured to isolate the RF generator 171 from other signals created within the processing chamber 100. For example, RF filter 174 is configured to isolate the RF generator 171 from the signals generated from the PV waveform generator 175 and the high voltage supply 173. The RF filter 174 may be any suitable filter that can protect the RF generator 171 such as a low-pass filter, a high-pass filter, a band-pass filter, or the like. In some embodiments, the frequency of the RF signal and the frequency of the RF filter 174 are the same. In another example the frequency of the RF signal and the RF filter 174 are different.

Power delivery line 163C electrically connects the output of the RF filter 174 to output node n1. Power delivery line 164A electrically connects output node n1 to sensor 190. Power delivery line 164B electrically connects the output of sensor 190 to substrate support base 107. Alternatively, sensor 190 and power delivery line 164B are optional and power delivery line 164A is electrically connected to substrate support base 107. In one configuration, the RF waveform has a frequency range between about 100 kHz and about 200 MHz, such as between 2 MHz and 40 MHz.

The power delivery lines 160-164B include electrical conductors that include a combination of coaxial cables, such as a flexible coaxial cable that is connected in series with a rigid coaxial cable, an insulated high-voltage corona-resistant hookup wire, a bare wire, a metal rod, an electrical connector, of any combination of the above.

The system controller 126, also referred to herein as a processing chamber controller, includes a central processing unit (CPU) 133, a memory 134, and support circuits 135. The system controller 126 is used to control the process sequence used to process the substrate 103. The CPU is a general-purpose computer processor configured for use in an industrial setting for controlling the processing chamber and sub-processors related thereto. The memory 134 described herein, which is generally non-volatile memory, can include random access memory, read-only memory, hard disk drive, or other suitable forms of digital storage, local or remote. The support circuits 135 are conventionally coupled to the CPU 133 and comprises cache, clock circuits, input/output subsystems, power supplied, and the like, and combinations thereof. Software instructions (program) and data can be coded and stored within the memory 134 for instructing a processor within the CPU 133. A software program (or computer instructions) readable by CPU 133 in the system controller 126 determines which tasks are performable by the components in the plasma processing system 10.

Typically, the program, which is readable by the CPU 133 in the system controller 126 includes code, which, when executed by the CPU 133, performs tasks relating to the plasma processing schemes described herein. The program may include instructions that are used to control the various hardware and electrical components within the plasma processing system 10 to perform the various process tasks and various process sequences.

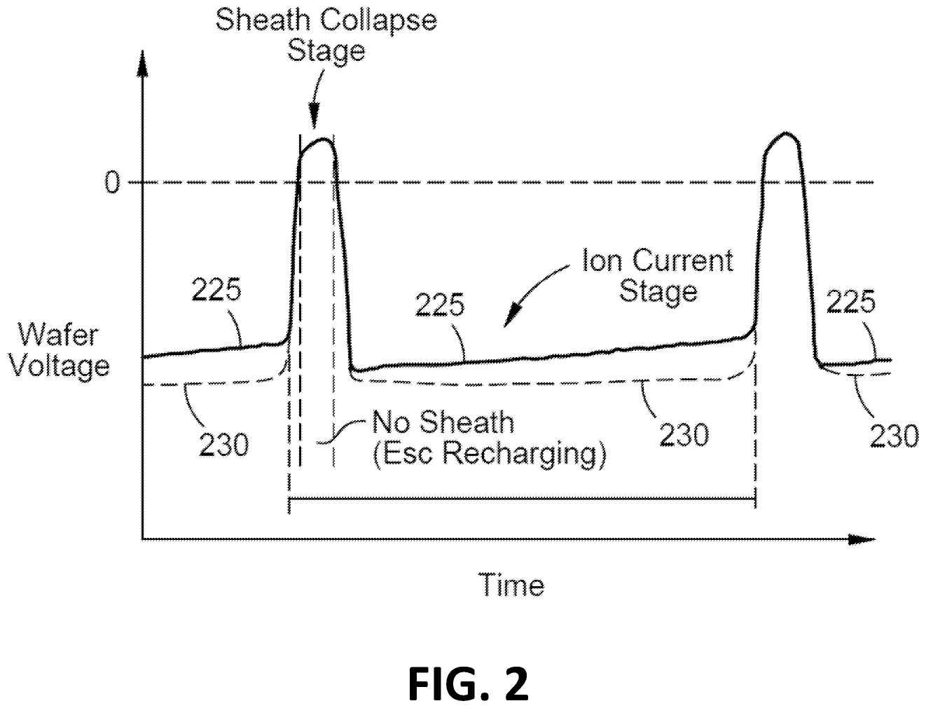

FIG. 2 illustrates two separate voltage waveforms established at the substrate 103 disposed on the substrate receiving surface 105A of the substrate support assembly 136 of the processing chamber 100 due to the delivery of PV waveforms to the biasing electrode 104 of the processing chamber 100. A first waveform (e.g., a waveform 225) is an example of a non-compensated PV waveform established at the substrate 103 during the plasma processing. A second waveform (e.g., a waveform 230) is an example of a compensated PV waveform established at the substrate 103 by applying a negative slope waveform to the substrate support base 107 of the processing chamber 100 during an “ion current stage” portion of the PV waveform cycle by use of a current source. The compensated PV waveform can alternatively be established by applying a negative voltage ramp during the ion current stage of the PV waveform generated by the PV waveform generator 175.

The waveforms 225 and 230 include two main stages: an ion current stage and a sheath collapse stage. Both portions (e.g., the ion current stage and the sheath collapse stage) of the waveforms 225 and 230, can be alternately and/or separately established at the substrate 103 during the plasma processing. Conventionally, at a beginning of the ion current stage, a drop in the voltage at the substrate 103 is created, due to the delivery of a negative portion of the PV waveform (e.g., the ion current portion) provided to the substrate support base 107 by the PV waveform generator 175, which creates a high voltage sheath above the substrate 103. The high voltage sheath allows the plasma generated positive ions to be accelerated towards the biased substrate 103 during the ion current stage, and thus, for RIE processes, controls the amount and characteristics of the etching process that occurs on the surface of the substrate 103 during the plasma processing. In some embodiments, it is desirable for the ion current stage to include a region of the PV waveform that achieves the voltage at the substrate 103 that is stable or minimally varying throughout the stage, as illustrated in FIG. 2 by the waveform 230. One will note that providing the PV waveform to the substrate support base 107 instead of the biasing electrode 104 reduces the voltage overshoot, ringing, and current spikes provided to the biasing electrode 104 of a plasma processing chamber 100, which reduces arcing, allows for a PV waveform with a higher voltage, and increases the margin of the voltage provided by the PV waveform generator 175 to the plasma processing chamber 100.

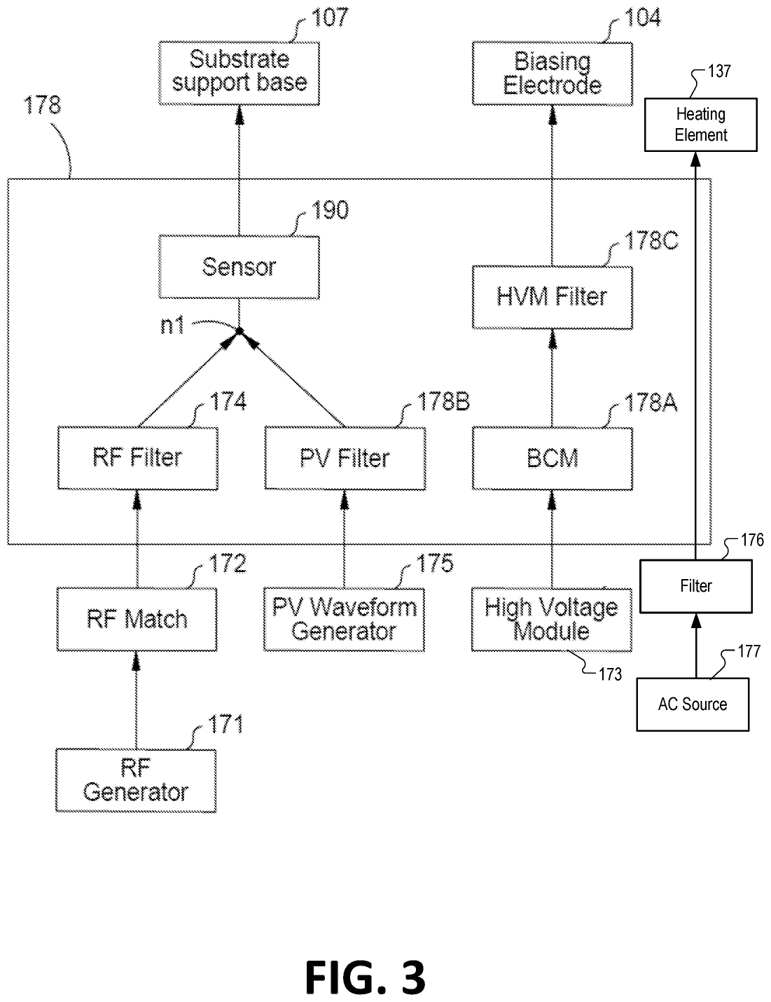

FIG. 3 is a schematic representation of a junction box 178 according to one or more embodiments. The junction box 178 may include RF filter 174, BCM 178A, PV filter 178B, HVM filter 178C, and sensor 190. In some embodiments, the junction box 178 receives inputs from the RF match 172, the PV waveform generator 175, and the high voltage supply 173. In another example, the RF match 172 is included in the junction box 178 and the RF generator 171 is directly coupled to the junction box 178.

The RF filter 174 may be electrically coupled to the RF match 172. The PV filter 178B may be electrically coupled to the PV waveform generator 175. The BCM 178A may be electrically coupled to the high voltage supply 173. The input of the sensor 190 may be electrically coupled to the RF filter 174 and the PV filter 178B via output node n1. The output of the sensor 190 may be electrically coupled to the substrate support base 107. The input of the HVM filter 178C may be electrically coupled to the BCM 178A. The output of the HVM filter 178C may be electrically coupled to the biasing electrode 104.

Each of the filters may be configured to isolate a corresponding signal generator from the other signals provided and generated in the processing chamber. For example, RF filter 174 may be configured to block the RF generator 171 from the signals generated from the PV waveform generator 175 and the high voltage supply 173 to avoid interference. PV filter 178B may be configured to block the PV waveform generator 175 from the signals generated from the RF generator 171 and the high voltage supply 173 to avoid interference. HVM filter 178C may be configured to block the high voltage supply 173 from the signals generated from the PV waveform generator 175 and the RF generator 171 to avoid interference.

In some embodiments, the sensor 190 may include a voltage sensor and/or a current sensor configured to measure the impedances or the characteristics of one of the plasma processing systems 10A, 10B, or 10C. The sensor 190 may include a voltage sensor and/or a current sensor configured to measure characteristics of the RF signal and the PV waveform such as voltage, current, phase, or harmonics. Sensor readings can be used in a feedback and feedforward algorithms for impedance matching. In some embodiments, the sensor 190 may be coupled to an RF match controller 302 of the RF match 172, and/or PV waveform generator 175. In another example, the sensor 190 is coupled to the RF match controller 302 and the RF match controller 302 provides the readings from the sensor 190 to the PV waveform generator 175 and/or the system controller 126. In some embodiments, based on the readings by the sensor 190 the RF match controller 302 adjusts the matching point of the RF match 172 so that the impedance of the output signal provided by the junction box 178 matches the impedance of the plasma processing chamber 100. In another example, based on the readings from the sensor 190, the PV waveform generator 175 adjusts properties of the PV waveform including, but not limited to, the rising and falling edges of the PV waveform, the duty cycle of the PV waveform, and the voltage of the PV waveform. In another example, the sensor 190 communicates to directly the system controller 126 and the system controller 126, based on the readings of the senor, adjusts the PV and RF waveforms accordingly via the RF generator 171 and the PV waveform generator 175. Based on the readings from the sensor 190, the RF generator adjusts properties of the RF waveform including, but not limited to, the power and/or pulsing of the RF waveform. In another example, the sensor 190 is optional. In some embodiments, the AC source 177 (and the filter 176) is electrically coupled to the heating element 137 via the junction box 178.

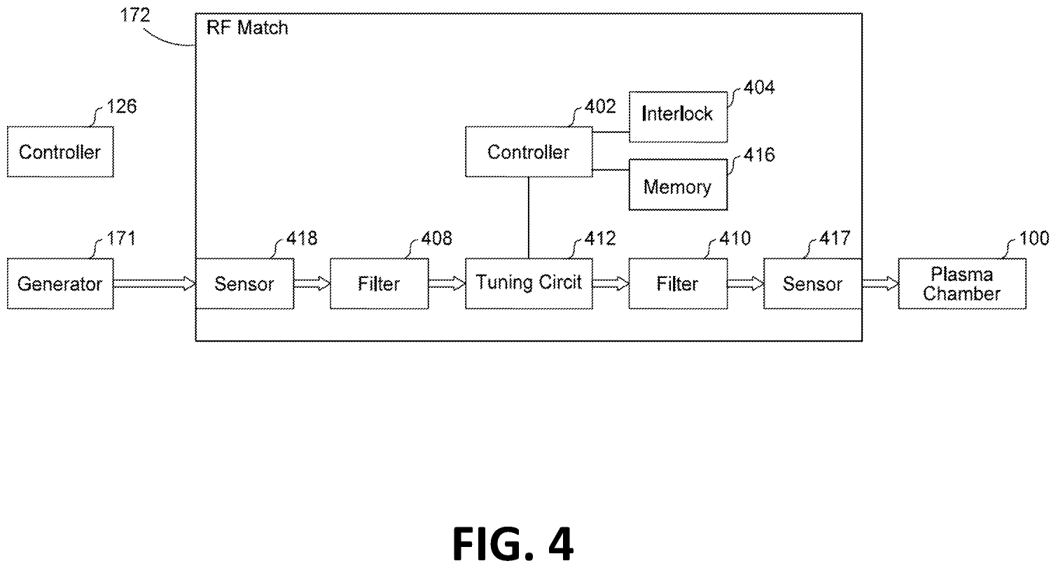

FIG. 4 is a schematic representation of a RF power delivery system, according to one or more embodiments. The RF match 172 includes an RF match controller 402, input sensor 418, and output sensor 417, a first RF filter 408, a second RF filter 410, a tuning circuit 412, an interlock 414, and a memory 416. The first RF filter 408 and the second RF filter 410 may be configured to block frequencies from other signals being transmitted from the processing chamber 100 to avoid interference at the RF generator 171. For example, the first RF filter 408 and the second RF filter 410 may be low-pass, high pass, or band pass filters.

In some embodiments, the RF match 172 is configured to receive an RF waveform from the RF generator 171, tune the RF waveform to reduce the reflected power and improve power delivery efficiency. The RF match 172 may deliver the tuned RF waveform to substrate support base 107 of processing chamber 100 via junction box 178. In some embodiments, as described above, the PV waveform generator 175 is configured to provide a PV waveform to substrate support base 107 of processing chamber 100 simultaneously with the tuned RF waveform. The RF generator 171 and the PV waveform generator 175 are both communicationally coupled to and synchronized by the system controller 126. The synchronization signal can be from the system controller 126, the PV waveform generator 175 or the RF generator 171.

The RF match controller 402 may be communicationally coupled to the interlock 414, the memory 416, the tuning circuit 412, the input sensor 418, the output sensor 417, and optionally, sensor 190 (see e.g., FIGS. 3A and 3C). In some embodiments, the RF match controller 402 is also in communication with an electronic device that includes a display and user interface, such as conventional computer (e.g., user PC), which may in some cases form part of the system controller 126. The RF match controller 402 may include a central processing unit (CPU). The RF match controller 402 may be configured to control the tuning circuit 412 to change an impedance parameter of the RF match 172. The tuning circuit 412 described herein may be a T-network tuning circuit, a pi-network tuning circuit, an L-network circuit, or the like. The tuning circuit 412 may include at least one electrical component, such as a variable capacitor and/or inductor that can be adjusted by the RF match controller 402 to change the impedance, so that the RF waveform delivered to the processing chamber 100 has been optimized. Thus, generating an adjusted RF signal. The tuning circuit 412 has an input 412A that is directly or indirectly coupled to the input sensor 418 and output 412B that is directly or indirectly coupled to the output sensor 417.

The memory 416 may be programmed for long term or short term memory storage. The memory 416 described herein, which is generally non-volatile memory, can include random access memory, read-only memory, hard disk drive, or other suitable forms of digital storage, local or remote. Software instructions (program) and data can be coded and stored within the memory 416 for instructing a processor within the controller 402. A software program (or computer instructions) readable by controller 402 determines which tasks are performable by the components in the plasma processing systems 10A, 10B, and/or 10C.

The interlock 414 may be implemented for safety purposes to control over temperature switches, cable-in-place switches, and match-in-place switches, etc. The interlock 414 is open when failure happens, and an interlock signal will be sent from a local microcontroller to both a user laptop and the system controller 126 to shut the system off.

The output sensor 417 may include a voltage sensor and/or a current sensor configured to measure the impedances or the characteristics of the plasma processing systems 10A, 10B, and/or 10C explained above. In some embodiments, when the sensor 190 (see e.g., FIGS. 3A and 3C) is included in the junction box 178, the output sensor 417 is optional. If the sensor 190 is not included in the junction box 178, the output sensor 417 is included in the RF match 172. The output sensor 417 may be located between the RF match 172 and the junction box 178, or may be included within the junction box 178. Stated differently, the output sensor 417 and/or sensor 190 may be located anywhere between the output of the RF match 172 and the substrate support base 107. The input sensor 418 may include a voltage sensor and/or a current sensor configured to measure characteristics of the RF waveform such as voltage, current, phase, or harmonics. In some embodiments, only one sensor can be used at the input of the RF match 172. Sensor readings may be used in a feedback and feedforward algorithms for impedance matching.

In some embodiments, as described above, the junction box 178 routes both a tuned RF waveform signal from the RF generator 171 and a PV waveform signal from PV waveform generator 175 to substrate support base 107. This may effectively decouple the PV waveform generator 175 from biasing electrode 104 and reduces the current provided to biasing electrode 104, reduces arcing, allows for a PV waveform with a higher voltage, and increases the voltage margin of the PV waveform generator 175 while maintaining the same etch rate.

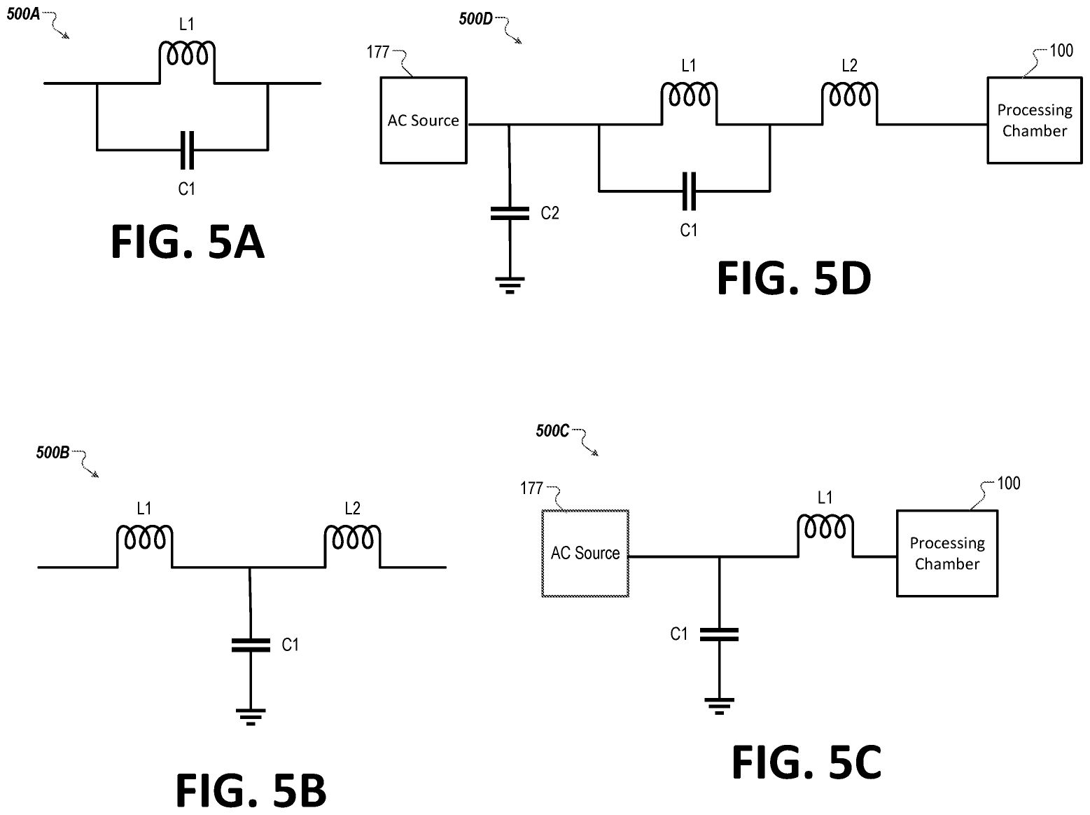

FIGS. 5A-D are schematic representations of analog filters 500A-D for a plasma processing system, according to one or more embodiments. Any one or more of the analog filters shown in FIGS. 5A-D may be included in filter 176 of FIGS. 1A and 1B. In some embodiments, any one of filters 500A-D may be used in series with a choke (e.g., a common mode choke).

Referring to FIG. 5A, a resonant circuit or band-stop filter 500A is shown. In some embodiments, filter 500A includes an inductor electrically in parallel with a capacitor. The inductor may have an inductance vale L1 and the capacitor may have a capacitance value C1. The values of L1 and C1 may be chosen to filter a particular frequency. For example, the values of L1 and C1 may be chosen so that an RF signal and/or a PV waveform signal (e.g., from a plasma processing chamber) cannot pass through the filter. In some embodiments, filter 500A can be tuned (e.g., by selecting values of L1 and C1) to filter a band of frequencies. In some embodiments, the inductor may be formed by an air-core coil as described herein.

Referring to FIG. 5B, a low-pass filter 500B is shown. In some embodiments, filter 500B includes a first inductor having an inductance value L1 and a second inductor having an inductance value L2. The filter 500B may include a capacitor having capacitance value C1. The capacitor may electrically couple the region between the inductors to ground. The values of L1, L2, and C2 may be chosen to filter a particular frequency. In some embodiments, either of the inductors of filter 500B may be formed by an air-core coil as described herein.

Referring to FIG. 5C, a low-pass filter 500C is shown. Filter 500C may be electrically coupled between AC source 177 and processing chamber 100. As described herein above, AC source 177 may supply one or more electrodes (e.g., heater electrodes, etc.) within processing chamber 100 with AC. Filter 500C may include an inductor and a capacitor. The values of L1 (of the inductor) and C1 (of the capacitor) may be selected to tune the filter 500C. For example, filter 500C can be tuned to filter RF signal and/or PV waveform signal frequencies that are harmful to AC source 177. In some embodiments, filter 500C may at least partially block an RF signal and/or a PV waveform signal from traveling through the AC power lines between the processing chamber 100 and the AC source 177. The filter 500C may therefore effectively protect the AC source 177 from damage that may be caused by an RF signal and/or a PV waveform signal. In some embodiments, the inductor of filter 500C may be formed by an air-core coil as described herein.

Referring to FIG. 5D, a combination filter 500D is shown. In some embodiments, filter 500D is a combination of filter 500A, filter 500B, and/or filter 500C. Filter 500D may be electrically coupled between AC source 177 and processing chamber 100 to block an RF signal and/or a PV waveform signal from reaching AC source 177. In some embodiments, filter 500D includes two capacitors and at least two inductors. A first inductor having an inductance value L1 may be electrically in parallel with a first capacitor having a capacitance value C1. Filter 500D may include a second capacitor electrically coupled to ground between the AC source 177 and the first inductor and first capacitor. The second capacitor may have a capacitance value of C2. Filter 500D may include a second inductor electrically coupled between the first inductor and first capacitor and the processing chamber 100. The second inductor may have an inductance value of L2. In some embodiments, the values of L1, L2, C1, and/or C2 may be selected to tune filter 500D to filter RF signal and/or PV waveform signal frequencies that are harmful to AC source 177. In some embodiments, either or both inductors of filter 500D may be formed by an air-core coil as described herein.

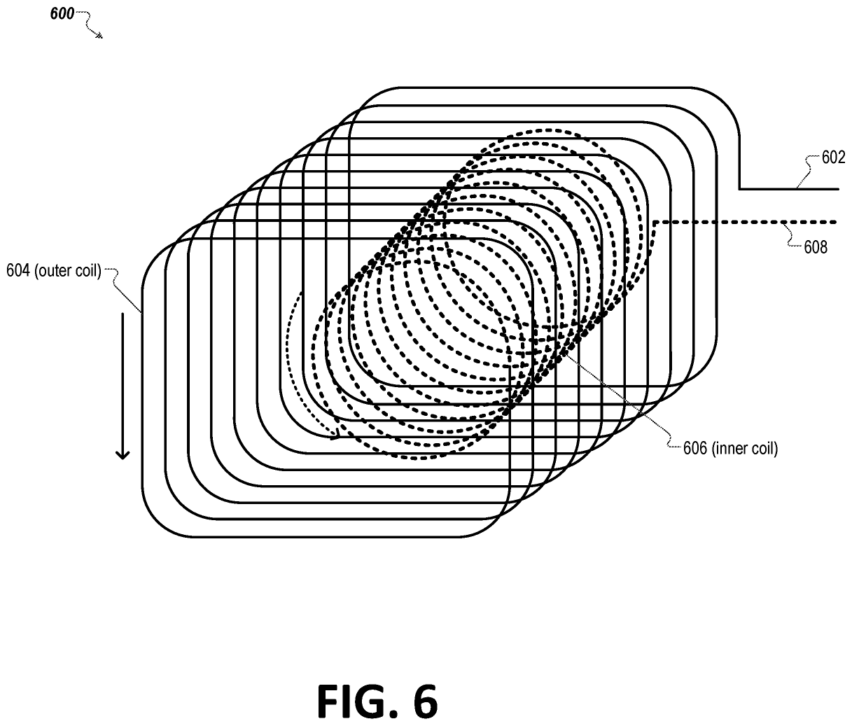

FIG. 6 is a simplified perspective view of an air-core coil 600, according to one or more embodiments. In some embodiments, air-core coil 600 includes an inner coil 606 wound inside an outer coil 604. In some embodiments, the inner coil 606 is electrically in-series with the outer coil 604. The inner coil 606 and/or the outer coil 604 may have an air core, meaning air may occupy space inside the coils of the outer coil 604 and/or the space inside the coils of inner coil 606. Air-core coil 600 has no iron core or other core material as typically found in inductors. In some embodiments, the outer coil 604 has a generally rectangular profile and the inner coil 606 has a generally circular profile.

The inner coil 606 and the outer coil 604 may be wound the same direction so that the magnetic flux generated by each of the coils does not cancel the magnetic flux generated by the other. Therefore, the inner coil 606 and the outer coil 604 may together form an inductor. Current may enter air-core coil at connection 602 and travel in an anti-clockwise direction through the coils of outer coil 604 (as indicated by the solid line arrow). After reaching the end of outer coil 604, the current may travel again in an anti-clockwise direction through the coils of inner coil 606 (as indicated by the dashed line arrow). The current may leave the air-core coil through connection 608. To conserve size (e.g., especially length), the inner coil 606 may be folded back with respect to the outer coil 604. In some embodiments, air-core coil 600 includes only an outer coil 604 (e.g., with no inner coil 606), but with a much longer length than as shown. In some embodiments, more coils can be added to the outer coil 604 and/or to the inner coil 606 to increase the inductance value of the air-core coil 600.

In some embodiments, air-core coil 600 includes three coils. For example, an outer coil may surround two inner coils. Both inner coils may be disposed side-by-side within the outer coil. In another example, an outer coil surrounds a middle coil and the middle coil surrounds an inner coil. The arrangement of three coils may be similar to the arrangement of two coils shown in FIG. 6. For example, the outer coil may have a substantially square or rectangular profile (as outer coil 604 is shown in FIG. 6 having a substantially rectangular profile) and the two inner coils may have a substantially circular profile (as inner coil 606 is shown in FIG. 6 having a substantially circular profile). The two inner coils may be disposed side-by-side within the outer coil. In some embodiments, all three coils may have substantially circular profiles with the inner coil disposed within the middle coil and the middle coil disposed within the outer coil.

While the foregoing is directed to embodiments of the present disclosure, other and further embodiments of the disclosure may be devised without departing from the basic scope thereof, and the scope thereof is determined by the claims that follow.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure can be practiced without these specific details. In other instances, well-known components or methods are not described in detail or are presented in simple block diagram format in order to avoid unnecessarily obscuring the present disclosure. Thus, the specific details set forth are merely exemplary. Particular implementations can vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “of” rather than an exclusive “or.” When the term “about” or “approximately” is used herein, this is intended to mean that the nominal value presented is precise within ±10%.

Although the operations of the methods herein are shown and described in a particular order, the order of operations of each method can be altered so that certain operations can be performed in an inverse order so that certain operations can be performed, at least in part, concurrently with other operations. In another embodiment, instructions or sub-operations of distinct operations can be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A system, comprising:
a processing chamber configured to perform a plasma process with respect to one or more substrates;
an electrostatic chuck disposed within the processing chamber, wherein the electrostatic chuck comprises one or more electrodes; and
an analog filter electrically coupled to at least one electrode of the one or more electrodes, wherein the analog filter comprises:
an air-core coil comprising a first coil and a second coil disposed within the first coil, wherein the first coil and the second coil together form an inductor.

2. The system of claim 1, further comprising:
one or more of a radio frequency (RF) generator configured to provide an RF signal to the processing chamber or a pulsed voltage (PV) waveform generator configured to provide a PV waveform signal to the processing chamber.

3. The system of claim 2, further comprising:
an electrical source to provide electrical energy for the one or more electrodes, wherein the analog filter is configured to protect the electrical source from damage from one or more of the RF signal or the PV waveform signal.

4. The system of claim 2, wherein the inductor is configured to at least partially block one or more of the RF signal or the PV waveform signal from passing through the air-core coil.

5. The system of claim 2, wherein one or more of the RF signal or the PV waveform signal has a frequency less than 50 megahertz (MHz).

6. The system of claim 1, wherein the one or more electrodes comprises at least one heater electrode.

7. The system of claim 6, wherein each of the at least one heater electrode is associated with one or more heating zones of the electrostatic chuck, and wherein a corresponding analog filter is electrically coupled to each of the at least one heater electrode.

8. The system of claim 1, wherein the analog filter further comprises a choke electrically in series with the air-core coil, and wherein the air-core coil is configured to at least partially prevent voltage saturation of the choke.

9. The system of claim 1, wherein the second coil is folded with respect to the first coil and wound in a same direction as the first coil.

10. The system of claim 1, wherein the analog filter comprises one or more of a low-pass filter or a band-stop filter.

11. A plasma processing system, comprising:
a pulsed voltage (PV) waveform generator configured to provide a PV waveform signal to a plasma processing chamber;
one or more electrodes disposed within a substrate support within the plasma processing chamber; and
an analog filter electrically coupled to at least one electrode of the one or more electrodes, wherein the analog filter comprises:
a choke electrically in series with an air-core coil, wherein the air-core coil forms an inductor.

12. The plasma processing system of claim 11, further comprising:
an electrical source to provide electrical energy for the one or more electrodes, wherein the analog filter is configured to protect the electrical source from damage from the PV waveform signal.

13. The plasma processing system of claim 11, wherein the inductor is configured to at least partially block the PV waveform signal from passing through the air-core coil.

14. The plasma processing system of claim 11, wherein the PV waveform signal has a frequency less than 2 megahertz (MHz).

15. The plasma processing system of claim 11, wherein the choke is a common mode choke, and wherein the air-core coil is configured to at least partially prevent voltage saturation of the choke.

16. The plasma processing system of claim 11, wherein the air-core coil comprises a first coil and a second coil disposed within the first coil.

17. The plasma processing system of claim 11, wherein the analog filter comprises one or more of a low-pass filter or a band-stop filter.

18. The plasma processing system of claim 11, wherein the one or more electrodes comprises at least one heater electrode.

19. An system, comprising:
one or more electrodes of a plasma processing chamber; and
an air-core coil electrically coupled to at least one of the one or more electrodes, the air-core coil comprising a first coil and a second coil electrically in series with the first coil, wherein the second coil is disposed within the first coil, and wherein the air-core coil forms an inductor configured to at least partially block one or more of a radio frequency (RF) signal or a pulsed voltage (PV) waveform signal from passing through the air-core coil.

20. The system of claim 19, wherein the second coil is folded with respect to the first coil and wound in a same direction as the first coil.
